(19) United States
(12) Patent Application Publication
(10) Pub. No.: US 2025/0362429 A1
(43) Pub. Date: Nov. 27, 2025

(54) SYSTEMS AND METHODS FOR SUBSURFACE MODELING

(71) Applicant: Schlumberger Technology Corporation, Sugar Land, TX (US)

(72) Inventors: Surya Sathujoda, Abingdon (GB); Soham Monishi Sheth, Abingdon (GB)

(21) Appl. No.: 19/218,441

(22) Filed: May 26, 2025

Related U.S. Application Data
(60) Provisional application No. 63/651,724, filed on May 24, 2024.

(51) Int. Cl. G01V 20/00; E21B 43/20; G06F 30/27

(52) U.S. Cl. CPC G01V 20/00; E21B 43/20; G06F 30/27; E21B 2200/20

(57) ABSTRACT

A method for modeling a subsurface reservoir includes receiving coarse-grid simulation results for the subsurface reservoir, the coarse-grid simulation results being based on a coarse-grid simulation of the subsurface reservoir and having a low resolution that is less than a high resolution. The method also includes generating a reservoir model using a subsurface simulation machine learning model. The subsurface simulation machine learning model is trained to denoise input noise samples using coarse-grid simulation samples as conditioning data to predict high-resolution target reservoir property fields at the high resolution. The high-resolution target reservoir property fields indicate a predicted structure and one or more predicted flow properties for target subsurface reservoirs. The method further includes providing the reservoir model for operating a wellbore based on the reservoir model.

This application claims priority to and the benefit of U.S. Provisional Patent Application No. 63/651,724, filed on May 24, 2024, which is hereby incorporated by reference in its entirety.

### BACKGROUND OF THE DISCLOSURE

Wellbores may be drilled into a surface location or seabed for a variety of exploratory or extraction purposes. For example, a wellbore may be drilled to access fluids, such as liquid and gaseous hydrocarbons, stored in subterranean formations and to extract the fluids from the formations. Wellbores used to produce or extract fluids may be formed in earthen formations using earth-boring tools such as drill bits for drilling wellbores and reamers for enlarging the diameters of wellbores.

One of the key steps associated with forming, accessing or otherwise utilizing wellbores is the study of the subsurface, including reconstruction of geological models. These models are typically scalar functions defined over a 2-dimensional or 3-dimensional space of interest, and aim to represent elements such as rock unit boundaries, faults, horizons, and reservoir boundaries and properties, among other subterranean features and characteristics. These models may be valuable for tasks such as structural gridding, geological property modeling, reservoir flow simulation, and so forth.

In this way, geological models are advantageous for various scientific and engineering purposes, including wellbore planning, production forecasting, and natural resource management.

### SUMMARY

In some embodiments, a method for modeling a subsurface reservoir includes receiving coarse-grid simulation results for the subsurface reservoir, wherein the coarse-grid simulation results are based on a coarse-grid simulation of the subsurface reservoir and have a low resolution that is less than a high resolution. The method also includes generating a reservoir model using a subsurface simulation machine learning model that is trained to denoise input noise samples using coarse-grid simulation samples as conditioning data to predict high-resolution target reservoir property fields at the high resolution, wherein the high-resolution target reservoir property fields indicate a predicted structure and one or more predicted flow properties for target subsurface reservoirs. The method further includes providing the reservoir model for operating a wellbore based on the reservoir model. In some embodiments, the method is performed by a computer system. In some embodiments, the method is performed as instructions stored on a computer-readable storage medium.

This summary is provided to introduce a selection of concepts that are further described in the detailed description. This summary is not intended to identify key or essential features of the claimed subject matter, nor is it intended to be used as an aid in limiting the scope of the claimed subject matter. Additional features and aspects of embodiments of the disclosure will be set forth herein, and in part will be obvious from the description, or may be learned by the practice of such embodiments.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is an example of a downhole system, according to at least one embodiment of the present disclosure;

FIG. 2A illustrates an example environment in which a subsurface modeling system is implemented, according to at least one embodiment of the present disclosure;

FIG. 2B illustrates an example implementation of a subsurface modeling system as described herein, according to at least one embodiment of the present disclosure;

FIG. 3 illustrates a block diagram example of generating high-resolution simulation results and corresponding coarse-grid simulation results, according to at least one embodiment of the present disclosure;

FIG. 4 illustrates a block diagram example of training a subsurface simulation denoising diffusion probabilistic model using simulation results generated by a reservoir simulator, according to at least one embodiment of the present disclosure;

FIG. 5 illustrates a block diagram example of utilizing a trained subsurface simulation denoising diffusion probabilistic model for generating high-resolution target reservoir property field, according to at least one embodiment of the present disclosure;

FIG. 6 illustrates an example three-dimensional reservoir model generated using high-resolution outputs produced by the subsurface modelling system, according to at least one embodiment of the present disclosure;

FIG. 7 illustrates an example time-evolving reservoir model generated using sequential high-resolution simulation outputs produced by the subsurface modeling system, according to at least one embodiment of the present disclosure;

FIG. 8 illustrates a flow diagram for a method 800 or a series of acts for modeling a subsurface reservoir, according to at least one embodiment of the present disclosure; and

FIG. 9 illustrates certain components that may be included within a computer system.

### DETAILED DESCRIPTION

This disclosure describes a subsurface modeling system that uses a physics-informed machine learning pipeline to generate high-resolution simulation outputs from low-resolution reservoir simulations. The subsurface modeling system may be integrated into or associated with a variety of reservoir engineering workflows, including drilling operations, production forecasting, carbon storage monitoring, or history matching. In some implementations, the subsurface modeling system includes a trained subsurface simulation machine learning (ML) model that generates high-resolution target reservoir property fields-such as saturation or pressure distributions-by applying a generative denoising process guided by coarse-grid simulation data and residuals. In this way, the system may provide high-resolution results without the computational expense of running a full fine-grid reservoir simulation.

More specifically, the subsurface modeling system receives coarse-grid simulation results for a subsurface reservoir, where the coarse-grid simulation represents a lower-resolution discretization of the reservoir domain. These low-resolution results are used as conditioning data for a subsurface simulation ML model trained to denoise input noise samples. During inference, the ML model and an associated sampler iteratively transform an initial random noise sample into a high-resolution prediction that reflects the structure and flow characteristics of the target reservoir. The resulting reservoir property fields may indicate pressure fronts, saturation gradients, or other time-dependent flow dynamics at a resolution not captured in the coarse-grid simulation. The predicted results can then be assembled into a reservoir model for use in downstream applications.

As will be discussed in further detail below, the present disclosure includes a number of practical applications having features described herein that provide benefits and/or solve problems associated with generating geological models and evaluating subsurface features. Some example benefits are discussed herein in connection with various features and functionalities provided by a subsurface modeling system implemented on one or more computing devices. It will be appreciated that benefits explicitly discussed in connection with one or more embodiments described herein are provided by way of example and are not intended to be an exhaustive list of all possible benefits of the subsurface modeling system.

For example, in many existing subsurface modeling workflows, generating high-resolution simulation outputs requires solving large-scale partial differential equations (PDEs) over fine-grid meshes using resource-intensive numerical methods. These simulations can often consume significant memory, CPU cycles, and data storage. The subsurface modeling system described herein reduces this computational expense by training a machine learning model to approximate the high-resolution solution, and by relying on only coarse-grid simulation results and minimal conditioning data as inputs. As a result, the system improves computer resource utilization, enabling high-fidelity modeling even on devices with limited memory and/or compute resources.

In addition to reducing resource usage in this way, the subsurface modeling system improves the runtime performance for computer systems generating high-simulation results. For instance, traditional fine-grid numerical solvers may require hours or days of computation per scenario. In contrast, the subsurface modeling system uses denoising machine learning techniques that can execute quickly to create predicted high-resolution simulation results that closely mirror those generated by full numerical simulations. Accordingly, the subsurface modeling system can deliver considerable improvements to simulation runtimes, in some cases providing high-resolution property field outputs in near real time.

These improvements to computer resource usage and operational runtime are further enhanced through the use of a static residual calculated from the coarse-grid simulation. For instance, some physics-informed machine learning systems may implement residual of governing systems of partial differential equations that are recalculated at each denoising step, introducing redundant computation and increased memory load. The subsurface modeling system, however, computes the residual once and reuses it statically as a conditioning signal across all denoising steps. This reduces per-step overhead, avoids redundant physics-based calculations, and improves the functional efficiency of the system during inference, while still enforcing physical consistency in the generated outputs.

Beyond efficiency and speed, the subsurface modeling system improves the accuracy and fidelity of predicted reservoir outputs over that which may be achieved with other machine learning reservoir simulation techniques. Because the machine learning models herein are trained using both coarse-grid simulation results and physics-based residuals, the models learn to capture critical features of fluid flow such as pressure discontinuities, saturation fronts, and fault-bounded compartments that would otherwise be under-resolved. This allows the subsurface modeling system to generate physically consistent, high-resolution property fields that are more representative of the true subsurface environment than traditional interpolation or image-based generative models. For instance, in contrast to other machine learning techniques that may learn direct mappings between low-resolution and high-resolution data without physics-based constraints, the subsurface modeling system, (e.g., by virtue of the denoising diffusion probabilistic modeling process it implements) uses physics-informed conditioning to guide the generative process, thereby avoiding unrealistic or hallucinated features. This ensures that the high-resolution predictions are not only visually plausible, but also physically grounded and consistent with the underlying reservoir dynamics.

The subsurface modeling system further improves modeling flexibility by supporting input data defined over non-uniform spatial grids. For instance, other machine learning-based simulation techniques may assume uniform, grid-like structures akin to images, limiting their applicability to realistic reservoir domains. The subsurface modeling system, however, can operates based on coarse-grid results and residuals from non-uniform, structured simulation meshes as inputs. This allows the subsurface modeling system to be directly applicable to subsurface reservoir simulation workflows without grid resampling, thereby increasing the system's compatibility and deployment flexibility across various real-world geologic settings.

In addition to these, and other, technical benefits, the subsurface modeling system provides practical applications associated with reservoir modeling use-cases. For instance, the subsurface modeling system may be deployed to generate high-resolution reservoir models that guide real-time well placement, monitor evolving saturation distributions, assess injection strategies in carbon storage applications, and other wellbore activities. The ability to use coarse-grid simulation data as inputs and generate reliable, high-fidelity outputs in near real time enables the subsurface modelling system to directly support field operations. Thus, the subsurface modeling system provides a specific solution to the computational constraints of traditional reservoir modeling.

As illustrated in the following discussion, this disclosure uses a variety of terms to describe the features and advantages of one or more implementations described in this disclosure. Additional details are provided to clarify the meaning of some of these terms, while details regarding other terms may be provided later in the document.

As used herein, a “reservoir” refers to a subsurface geological formation that contains or is expected to contain fluids such as hydrocarbons, water, gas, or carbon dioxide. A reservoir may include porous rock or sedimentary structures through which fluids can flow, and may be defined by spatial boundaries such as faults, permeability barriers, or stratigraphic discontinuities. In some instances, a reservoir may be modeled using a discretized mesh or grid, including either a uniform or non-uniform distribution of cells that represent spatially varying properties. A “reservoir property field” refers to a multi-dimensional dataset (e.g., 2D, 3D, or 4D) representing physical properties of the reservoir predicted or simulated over a given domain, such as pressure, water saturation, oil saturation, gas saturation, porosity, temperature, or other properties.

As used herein, a “machine learning model” refers to a computer-based computational model configured to learn a mapping or transformation from input data to output data through an optimization process involving training data. Machine learning models may be models that are trained to approximate unknown functions. A machine learning model may include, but is not limited to, a neural network such as a convolutional neural network (CNN), a generative model such as a generative adversarial network (GAN), or a denoising diffusion probabilistic model (DDPM).

A “generative model” refers to a machine learning model that is trained to synthesize new data instances that resemble a training distribution. In some cases, generative machine learning models describe herein may be “conditioned” on additional data injected into the model at inference or training time to guide the model toward physically consistent results. A “denoising diffusion probabilistic model” (DDPM) is a type of generative model that produces output samples by reversing a multi-step stochastic diffusion process in which training data is gradually noised, and then denoised using a learned noise prediction network during inference.

As used herein, the term “simulation” refers to the computational modeling of fluid flow and property evolution within a reservoir, typically performed using a numerical reservoir simulator. A simulation may solve systems of partial differential equations governing multiphase flow, heat transfer, and other subsurface processes using a discretized spatial and temporal grid. A “coarse-grid simulation” refers to a simulation run over a lower-resolution grid, with fewer cells or elements per spatial dimension, resulting in faster computational performance but lower detail and accuracy. For example, a coarse-grid simulation may model a reservoir using a 10×10×10 grid, representing a simplified spatial resolution of the domain. In some cases, a coarse-grid simulation may be performed on a low-resolution grid having at most 40 cells per dimension, such as 10, 20, 30, 40 cells per dimension, or any value therebetween. A “fine-grid simulation” or “high-resolution simulation” refers to a simulation run over a denser grid that captures more spatial detail, such as a 100×100×100 or greater grid, but typically requires significantly greater computational resources. For instance, a fine-grid simulation may be performed on a high-resolution grid having at least 50 cells per dimension, such as 50, 60, 80, 100, 120, 150, 160, or more cells per dimension, or any value therebetween. The term “simulation results” refers to the outputs of such simulations at a given resolution, time step, and/or depth interval. The simulation results may include volumetric distributions of pressure, saturation, or other reservoir properties. The simulation results may have a resolution corresponding to the resolution of the associated grid of the simulation. These example resolutions for the coarse-grid simulation and the high-resolution should be understood as illustrative, and the resolution of the coarse-grid simulation and the high-resolution may be any other resolution, for example, as dictated by a size of an underlying reservoir simulation.

As used herein, the term “residual” refers to a numerical value or multi-dimensional field representing the mismatch or error between a simulated solution and the expected solution of a governing physical equation, such as a partial differential equation. Residuals may be computed by evaluating the difference between the modeled value and the value required to satisfy a conservation law or flow equation within a simulation grid cell. In the present disclosure, a “static residual” refers to a residual computed once, typically from a coarse-grid simulation, and then used as conditioning input to a machine learning model during training or inference, without being recomputed at each generation step. The residual helps to enforce physical realism and constraint satisfaction in the ML-generated outputs while reducing computational overhead.

Additional terms may be defined elsewhere in this disclosure in connection with specific examples, implementations, and contexts.

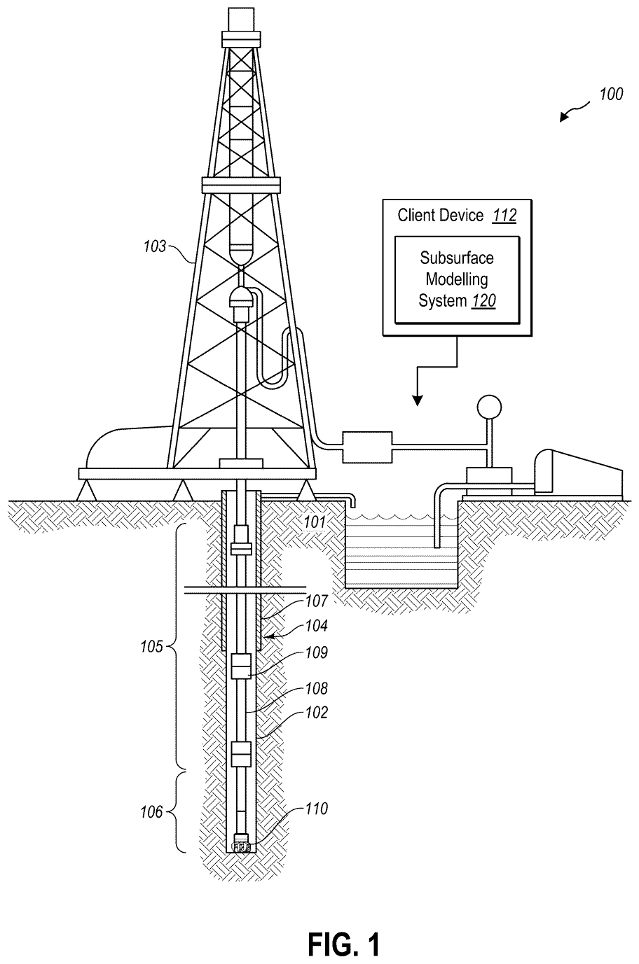

FIG. 1 shows one example of a downhole system 100 for drilling an earth formation 101 to form a wellbore 102. The downhole system 100 includes a drill rig 103 used to turn a drilling tool assembly 104 which extends downward into the wellbore 102. The drilling tool assembly 104 may include a drill string 105, a bottomhole assembly (“BHA”) 106, and a bit 110, attached to the downhole end of the drill string 105.

The drill string 105 may include several joints of drill pipe 108 connected end-to-end through tool joints 109. The drill string 105 transmits drilling fluid through a central bore and transmits rotational power from the drill rig 103 to the BHA 106. In some embodiments, the drill string 105 further includes additional downhole drilling tools and/or components such as subs, pup joints, etc. The drill pipe 108 provides a hydraulic passage through which drilling fluid is pumped from the surface. The drilling fluid discharges through selected-size nozzles, jets, or other orifices in the bit 110 for the purposes of cooling the bit 110 and cutting structures thereon, and for lifting cuttings out of the wellbore 102 as it is being drilled.

The BHA 106 may include the bit 110, other downhole drilling tools, or other components. An example BHA 106 may include additional or other downhole drilling tools or components (e.g., coupled between the drill string 105 and the bit 110). Examples of additional BHA components include drill collars, stabilizers, measurement-while-drilling (“MWD”) tools, logging-while-drilling (“LWD”) tools, downhole motors, underreamers, section mills, hydraulic disconnects, jars, vibration or dampening tools, other components, or combinations of the foregoing.

In general, the downhole system 100 may include other downhole drilling tools, components, and accessories such as special valves (e.g., kelly cocks, blowout preventers, and safety valves). Additional components included in the downhole system 100 may be considered a part of the drilling tool assembly 104, the drill string 105, or a part of the BHA 106, depending on their locations in the downhole system 100.

The bit 110 in the BHA 106 may be any type of bit suitable for degrading downhole materials. For instance, the bit 110 may be a drill bit suitable for drilling the earth formation 101. Example types of drill bits used for drilling earth formations are fixed-cutter or drag bits. In other embodiments, the bit 110 may be a mill used for removing metal, composite, elastomer, other materials downhole, or combinations thereof. For instance, the bit 110 may be used with a whipstock to mill into casing 107 lining the wellbore 102. The bit 110 may also be a junk mill used to mill away tools, plugs, cement, other materials within the wellbore 102, or combinations thereof. Swarf or other cuttings formed by use of a mill may be lifted to the surface 111 or may be allowed to fall downhole. The bit 110 may include one or more cutting elements for degrading the earth formation 101.

The BHA 106 may further include a rotary steerable system (RSS). The RSS may include directional drilling tools that change a direction of the bit 110, and thereby the trajectory of the wellbore. At least a portion of the RSS may maintain a geostationary position relative to an absolute reference frame, such as one or more of gravity, magnetic north, or true north. Using measurements obtained with the geostationary position, the RSS may locate the bit 110, change the course of the bit 110, and direct the directional drilling tools on a projected trajectory. The RSS may steer the bit 110 in accordance with or based on a trajectory for the bit 110. For example, a trajectory may be determined for directing the bit 110 toward one or more subterranean targets such as an oil or gas reservoir.

The downhole system 100 may include or may be associated with a client device 112 with a subsurface modeling system 120 implemented thereon (e.g., or with a client application implemented thereon for accessing the subsurface modeling system 120 as described herein). The subsurface modeling system 120 may facilitate generating geophysical models representing subsurface features.

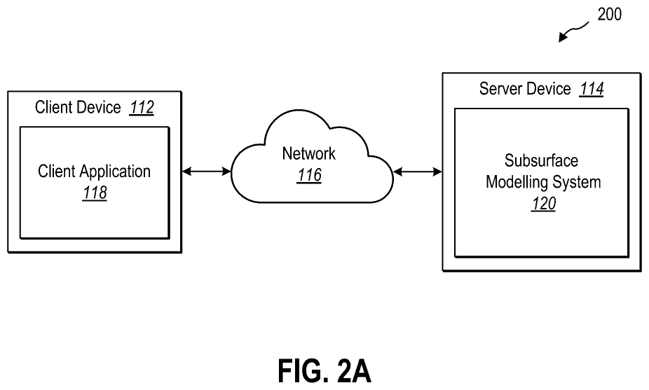

FIG. 2A illustrates an example environment 200 in which a subsurface modeling system 120 is implemented in accordance with one or more embodiments describe herein. As shown in FIG. 2A, the environment 200 includes a server device 114. The server device 114 may include one or more computing devices (e.g., including processing units, data storage, etc.) organized in an architecture with various network interfaces for connecting to and providing data management and distribution across one or more client systems. As shown in FIG. 2A, the server device 114 may be connected to and may communicate with (either directly or indirectly) a client device 112 through a network 116. The network 116 may include one or multiple networks and may use one or more communication platforms and/or technologies suitable for transmitting data. The network 116 may refer to any data link that enables transport of electronic data between devices of the environment 200. The network 116 may refer to a hardwired network, a wireless network, or a combination of a hardwired network and a wireless network. In one or more embodiments, the network 116 includes the internet. The network 116 may be configured to facilitate communication between the various computing devices via well-site information transfer standard markup language (WITSML) or similar protocol, or any other protocol or form of communication.

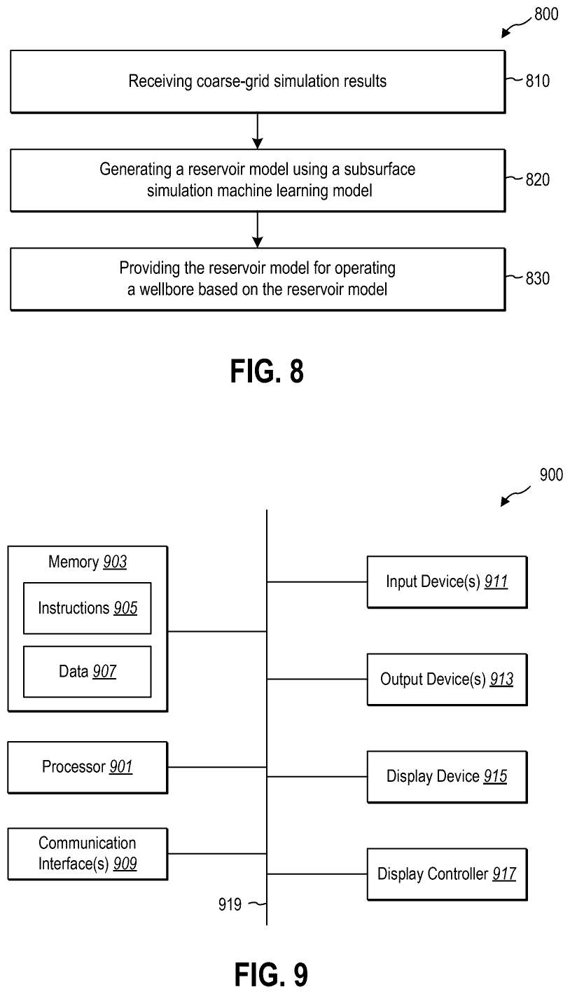

The client device 112 may be representative of one or multiple client devices, and may refer to various types of computing devices. For example, the client device 112 may include a mobile device such as a mobile telephone, a smartphone, a personal digital assistant (PDA), a tablet, a laptop, or any other portable device. Additionally, or alternatively, the client device 112 may include one or more non-mobile devices such as a desktop computer, server device, surface or downhole processor or computer (e.g., associated with a sensor, system, or function of the downhole system), or other non-portable device. In one or more implementations, the client device 112 includes graphical user interfaces (GUI) thereon (e.g., a screen of a mobile device). In addition, or as an alternative, one or more of the client device 112 may be communicatively coupled (e.g., wired or wirelessly) to a display device having a graphical user interface thereon for providing a display of system content. The server device 114 may similarly refer to various types of computing devices. Each of the devices of the environment 200 may include features and/or functionalities described below in connection with FIG. 9.

As shown in FIG. 2A, the environment 200 may include a subsurface modeling system 120 implemented on the server device 114. While shown on the server device 114, the subsurface modeling system 120 may be implemented wholly or in part on the client device 112, across the server device 114 and the client device 112, or on or across one or more additional devices, such that different portions or components of the subsurface modeling system 120 are implemented on different computing devices in the environment 200. The client device 112 may include a client application 118. The client application 118 may include an application or interface for interacting with and/or receiving the features of the subsurface modeling system 120 as described herein. In some embodiments, one or more of the functionalities or features of the subsurface modeling system 120 may be carried out or performed on or by the client application 118. In this way, the environment 200 may be a cloud computing environment, and the subsurface modeling system 120 may be implemented across one or more devices of the cloud computing environment in order to leverage the processing capabilities, memory capabilities, connectivity, speed, etc., that such cloud computing environments offer in order to facilitate the features and functionalities described herein.

FIG. 2B illustrates an example implementation of the subsurface modeling system 120 as described herein, according to at least one embodiment of the present disclosure. The subsurface modeling system 120 may include various components, as well as functionalities which may be described with respect to the various components. For example, a reservoir simulation manager 122 may facilitate executing numerical reservoir simulations using a reservoir simulator 130. The reservoir simulations may be performed on coarse-resolution grids or fine-resolution grids in order to produce high- and low-resolution simulation results for the purposes of the machine learning techniques described herein. A simulation results manager 124 may collect and manage simulation output data from the reservoir simulator 130, including pressure, saturation, or other fluid property fields generated over time, for instance, for generating simulation results. The simulation results manager 124 may also calculate residuals for coarse-resolution simulation results based on the governing partial differential equations used by the reservoir simulator 130.

The subsurface modeling system 120 may implement machine learning techniques for generating high-resolution reservoir property fields. For example, a machine learning model manager 126 may train and implement a reservoir simulation denoising diffusion probabilistic model (DDPM) 132 for upscaling coarse-grid simulation results to fine-grid, high-resolution property fields. The reservoir simulation DDPM 132 may be trained using coarse-grid simulation results, associated simulation residuals, and known high-resolution simulation results, and may implement a generative architecture (e.g., a U-Net) conditioned on the coarse input and residuals. A reservoir model manager 128 may facilitate generating and/or providing a reservoir model based on the reservoir property field outputs of the reservoir simulation DDPM 132 and may facilitate applying the reservoir model to downstream tasks such as history matching, production forecasting, or uncertainty quantification.

The subsurface modeling system 120 also includes a data storage 134 with various data stored thereon. For example, the data storage 134 includes reservoir simulations 136 and reservoir simulation results 138, which may include high-resolution simulation results 140 and coarse-grid simulation results 142. The data storage 134 may further store noise schedules 144 for use in the diffusion modeling process, as well as coarse-grid simulation residuals 146 associated with underlying systems of partial differential equations (PDEs) of the reservoir simulator 130. The data storage 134 also includes reservoir models 148 generated from the output of machine learning techniques described herein.

While one or more embodiments described herein describe features and functionalities performed by the specific components 120-148 of the subsurface modeling system 120, it will be appreciated that specific features described in connection with one component of the subsurface modeling system 120 may, in some examples, be performed by one or more of the other components of the subsurface modeling system 120. Indeed, it will be appreciated that some or all of the specific components may be combined into other components and specific functions may be performed by one or across multiple components 120-148 of the subsurface modeling system 120.

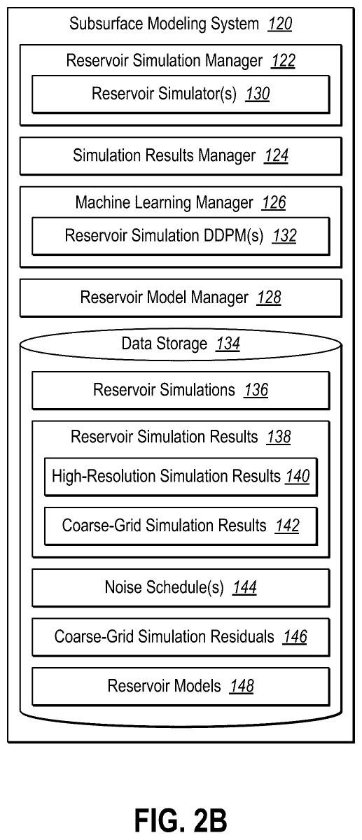

Referring now to FIG. 3, this figure illustrates a block diagram example of a workflow 300 for generating high-resolution simulation results 340 and corresponding coarse-grid simulation results 342, according to at least one embodiment of the present disclosure. In some embodiments, the subsurface modeling system 120 may implement a reservoir simulator 130 configured to execute numerical reservoir simulations 136 of subsurface fluid flow. The reservoir simulator 130 may simulate fluid behavior in porous media over time, based on geologic and engineering parameters such as rock permeability, porosity, pressure, saturation, fluid properties, injection and production well configurations, and boundary conditions. The reservoir simulator 130 may model the physical system using finite-volume or finite-difference discretizations of one or more partial differential equations (PDEs) that describe fluid transport and mass conservation within subsurface formations.

In various implementations, the reservoir simulator 130 may numerically solve and/or numerically estimate time-dependent, nonlinear PDEs that govern multiphase flow in porous media. For instance, the simulator may be based on conservation of mass for each fluid phase, Darcy's law for fluid motion, and/or constitutive relations for phase behavior. The underlying equations may include the continuity equation and multiphase extensions of Darcy's law, which together form a coupled PDE system solved iteratively over time. The equations may account for capillary pressure, relative permeability, fluid compressibility, and other nonlinear phenomena commonly encountered in oil and gas reservoirs, CO₂ storage formations, water injection systems, and/or other fluid-containing subsurface structures. In some cases, solving these equations with high fidelity across space and time requires computationally intensive operations, particularly when the domain is discretized using fine-resolution grids. In accordance with one embodiment of the present disclosure, the simulation is based on the following formula:

$$∇ \cdot [ α K \frac{{k}_{r , m} ( {S}_{m} )}{{μ}_{m} {B}_{m}} ( ∇ {p}_{m} - {γ}_{m} ∇ z ) ] - β \frac{\partial }{\partial t} ( ∅ \frac{{S}_{m}}{{B}_{m}} ) + {\sum }_{ω} \frac{{q}_{sc , m}^{ω}}{{V}_{b}} = 0$$

$$Where :$$

$$k denotes the permeability ,$$

$${k}_{r} relative permeability ,$$

$$μ is viscosity ,$$

$$B is the formation volume factor ,$$

$$p is pressure ,$$

$$S is saturation ,$$

$$∅ is porosity ,$$

$$t is time ,$$

$$γ is specific weight ,$$

$$Q is the source / sink terms ,$$

$$Z is depth ,$$

$${V}_{b} is the bulk volume , and$$

$$α and β are unit field constants .$$

The reservoir simulations 136 performed by the reservoir simulator 130 may include both a fine-grid simulation 150 and a coarse-grid simulation 152. Each of these simulations may represent the same subsurface model but differ in spatial resolution. For example, a fine-grid simulation 150 may discretize the reservoir domain into a grid of up to several million cells (e.g., 100×100×100), capturing high-resolution geological heterogeneities such as thin layers, fractures, or near-wellbore details. In contrast, a coarse-grid simulation 152 may simplify the domain using significantly fewer cells (e.g., 20×20×20), reducing the spatial fidelity of the model but at advantageously faster runtimes.

The fine-grid simulation 150 may serve as a physically accurate reference model and may be generated as a baseline or ground truth for comparison in connection with the ML techniques described herein. The simulation results manager 124 may receive outputs from the fine-grid simulation 150 and generate the high-resolution simulation results 340, which may include structured fields of pressure, saturation, velocity, or other fluid properties over time. These high-resolution simulation results 340 may be formatted as 2D or 3D spatial arrays or tensors, optionally sliced into temporal or spatial segments suitable for use as training data in machine learning applications described in further detail below. For instance, in some cases the simulation results (e.g., high-resolution and/or coarse grid simulation results) may be 2-dimensional slices or representations of a 3-dimensional model of the fine-grid simulation 150.

The coarse-grid simulation 152 may be executed by the same reservoir simulator 130 using the same physical inputs (e.g., permeability, porosity, well settings), but on a coarser spatial grid. The simulation results manager 124 may receive the outputs of the coarse-grid simulation 152 and generate the coarse-grid simulation results 342. These results may contain lower-resolution representations of the same fluid properties (e.g., saturation, pressure) but sampled over a coarser mesh. As a result, fine-scale heterogeneities are often smoothed or omitted in the coarse-grid simulation results 342. These results may be obtained through significantly lower computational cost, and may advantageously form the basis for generating upscaled predictions using the ML techniques described herein.

In various implementations, the fine-grid simulation 150 and/or the coarse-grid simulation 152 executed by the reservoir simulator 130 may be performed over non-uniform computational grids. In some cases, a non-uniform grid may include cells of varying dimensions, aspect ratios, or orientations, which are often required to accurately model geological features such as faults, pinch-outs, high-permeability channels, and near-wellbore refinement zones. Unlike uniform (e.g., Cartesian) grids typically used in image-based modeling, non-uniform grids in reservoir simulation can reflect the true spatial heterogeneity of subsurface formations. Accordingly, the high-resolution simulation results 340 and/or the coarse-grid simulation results 342 may contain property fields sampled over irregularly spaced grid cells, which may introduce additional complexity into the training and implementing of ML techniques for interpreting and/or upscaling those results.

The subsurface modeling system 120 operating based on non-uniform and/or heterogeneous grids may be in contrast to other (e.g., conventional) fluid property field simulation techniques. For example, some physics-informed generative modeling techniques may assume or implement uniform 2D grid structures for simplification and/or computational convenience. However, such an assumption can limit the usefulness of such techniques for applications to real-world reservoir problems. For instance, simplification in this way may be limited to single-phase and/or low-complexity flow fields, and may not be suited for capturing multiphase fluid flow and high geological complexity, such as subsurface discontinuities and non-uniformities. In contrast, the subsurface modeling system 120 is configured to utilize both coarse-grid simulation results 342 and residuals defined over non-uniform meshes as conditioning data for generative machine learning model techniques. This uniquely enables the subsurface modeling system 120 to meaningfully represent spatial correlations and provide physics-based upscaling for simulates performed over irregular grids. For instance, the subsurface modeling system 120 can support non-uniform grids in this way without requiring resampling or interpolation into uniform formats, and advantageously provide practical, physically grounded solutions for applications in reservoir simulation of real-world subsurface environments.

In some implementations, in addition to grid non-uniformities, the reservoir simulation 136 may include spatial discontinuities, which may be represented in the reservoir property fields of the simulation results. For instance, subsurface reservoirs may exhibit abrupt changes in pressure, saturation, permeability, or other quantities which the reservoir simulation 136 may represent as corresponding abrupt changes across adjacent cells. Discontinuities may be associated with geologic features such as faults, flow barriers, pinch-outs, or strong fluid front gradients. Discontinuities in this way may be inherent and physically significant aspects of a subsurface reservoir, and accurately modeling these discontinuities may result in sharp local deviations in property values that cannot be accurately captured by coarse-grid simulations alone. Accordingly, these discontinuities may manifest as elevated values in the coarse-grid residual 346, where the underlying PDEs are not well satisfied due to limitations in spatial resolution.

In some cases, the subsurface modeling system 120 may advantageously operate on reservoir simulations that include discontinuities in this way by detecting and representing such discontinuities through the coarse-grid residual 346 (described in more detail below). For instance, in contrast to other generative model-based simulation techniques which often operate on smooth, continuous data defined over uniform grids, the subsurface modeling system 120 is configured to operate on and utilize residuals that reflect real-world spatial irregularities and flow discontinuities within the reservoir. The residual can be utilized in the generative inference process to facilitate generating high-resolution reservoir property fields that preserve or restore discontinuous flow behavior. The discontinuities in this way may be honored via the residual in order to maintain the physical realism (and discontinuous nature) of the output. In this way, the subsurface modeling system 120 may be advantageously configured to handle discontinuities for facilitating accurate modeling of complex multiphase reservoir systems that would otherwise be poorly represented by coarse or smoothed inputs.

Accordingly, the simulation results represent spatial property fields computed by the reservoir simulator 130, such as pressure, fluid saturation, or velocity, distributed over a two-dimensional or three-dimensional computational grid. For instance, the reservoir simulation 136 may be a 3-dimensional simulation, and the simulation results manager 124 may accordingly slice or segment the 3-dimensional simulation to obtain 2-dimensional property fields. In some cases, the high-resolution simulation results 340 and the coarse-grid simulation results 342 may be 3-dimensional property volumes, and the techniques described herein may be implemented with respect to these 3-dimensional data samples. These property fields may vary over space and time, and the simulation results capture the dynamic behavior of fluids within the reservoir domain. For instance, the reservoir simulation 136 may represent various reservoir properties as they change with respect to time. In some cases, the simulation results represent a discrete time step or interval (e.g., a snapshot), for a past or future state of the reservoir. Accordingly, by generating and aggregating multiple simulation results for multiple discrete times over a given interval, a time-dependent representation of the reservoir can be represented via the simulation results. The simulation results may be structured as a tensor or multidimensional array corresponding to the simulation grid, with values assigned to individual cells based on the numerical solution of the governing physical equations. For instance, the simulation results may facilitate interpretation and/or characterization of a subsurface reservoir.

As mentioned, in addition to generating simulation results, the simulation results manager 124 may calculate a coarse-grid residual 346 based on the outputs of the coarse-grid simulation 152. The coarse-grid residual 346 may be a numerical measure of how well the solution at each grid point of the coarse-grid simulation 152 satisfies the underlying PDEs of the reservoir simulator 130. For example, the residual may be determined as the difference between the left-hand side and right-hand side of the discretized conservation equations.

The coarse-grid residual 346 may be computed using internal representations within the reservoir simulator 130, including grid geometry, transmissibility values, well source terms, and boundary conditions. In some implementations, the residual 346 may be formatted as a 3D tensor field or a structured array that maps each coarse cell to a corresponding residual value. These values reflect the deviation from mass conservation, momentum balance, or other structural or fluid properties at each location in the simulation. By quantifying where and to what degree the coarse-grid simulation 152 deviates from the expected reservoir behavior, the residual provides valuable physics-based insight into the precision and accuracy of the coarse-grid simulation 152. For instance, as described herein, the coarse-grid residual 346 can be provided as guidance or conditioning for generating high-resolution reservoir property fields from the coarse-grid simulation results 342.

In some cases, the coarse grid residual 346 is a static residual. For instance, the coarse-grid residual 346 may be calculated or determined once for the coarse-grid simulation 152 and utilized in connection with the coarse-grid simulation results 342 for downstream ML conditioning purposes (e.g., as static conditioning data). In contrast, some conventional solutions may perform fluid flow simulations and utilize residuals as conditioning variables, but may determine or update the conditioning variables one or more times by recalculating and updating the residual. For instance, dynamic residuals may be recalculating at various (or all) steps of a denoising process. Such a dynamic, recalculated residual in this way may come at the expense of increased computational cost. Accordingly, dynamic residual use may be realistically limited to static, simpler, and/or uniform 2-dimensional grid meshes in which mass residual recalculation is computationally feasible and does not create bottleneck issues.

The subsurface modeling system 120, however, may determine the coarse-grid residual 346 as a static residual, and may utilize the static residual end-to-end throughout the application and processing of the associated coarse-grid simulation results 342. The use of a static residual in this way may save on computation time and resources which may be particularly useful with respect to the reservoir simulations described. For example, subsurface reservoir simulations may be more computationally demanding that other, simpler fluid simulations for which other solutions are adapted. Indeed, for the physically complex, time-dependent, non-uniform, and/or 3-dimensional reservoir systems for which the subsurface modeling system 120 is implemented, it may not be computationally feasible to recalculate the residual one or more times, and even less so for each step of a denoising process. Thus, while using a dynamic residual, in some cases, could provide increased accuracy and improved physical constraints for the generative upscaling process, a dynamic residual may be prohibitively slow and/or computationally expensive for the complex reservoir systems described herein. In some cases, calculating the coarse-grid residual 346 once and utilizing it as a static conditioning variable may sacrifice at least some accuracy over dynamic residual techniques, but may nevertheless provide valuable physics-based guidance for the generative upscaling process to create accurate and useful property fields. In this way, implementing static residuals can provide an advantageous balance of accuracy and computational efficiency.

Accordingly, the reservoir simulator 130 generates both the fine-grid simulation 150 and coarse-grid simulation 152, from which the simulation results manager 124 derives the high-resolution simulation results 340, the coarse-grid simulation results 342, and the coarse-grid residual 346. These outputs can be utilized for training and applying generative ML model techniques for super-resolution of reservoir simulation data.

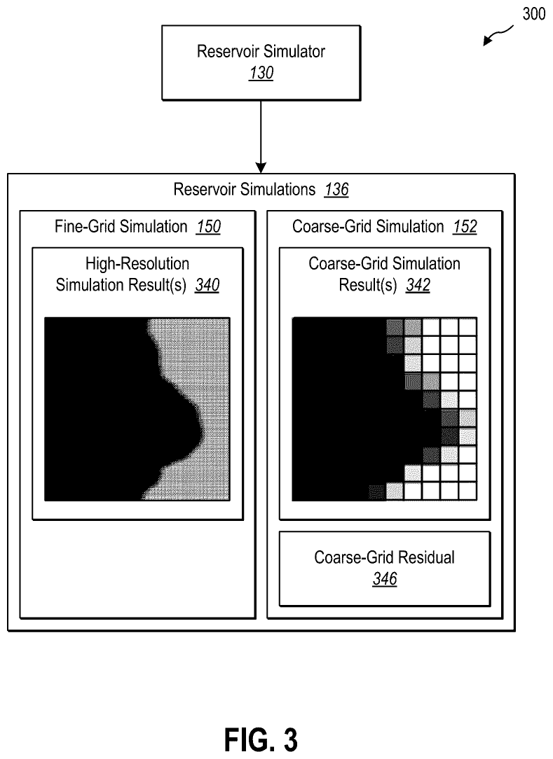

FIG. 4 illustrates a block diagram example of a workflow 400 for training a subsurface simulation DDPM 432 using simulation results generated by a reservoir simulator, according to at least one embodiment of the present disclosure. As described above with respect to FIG. 3, the reservoir simulator 130 may facilitate generating high-resolution simulation results 340, coarse-grid simulation results 342, and a coarse-grid residual 346.

As shown in FIG. 4, a training dataset 454 includes the high-resolution simulation results 340, as well as conditioning data 456. As described above, the high-resolution simulation results 340 may represent spatial property fields (e.g., pressure or saturation) over a high-resolution (potentially non-uniform) grid generated by a fine-grid simulation. The conditioning data 456 may include the coarse-grid simulation results 342 and the coarse-grid residual 346, each derived from a coarse-grid simulation. The coarse-grid simulation results 342 may contain lower-resolution spatial property fields over a coarser grid, while the coarse-grid residual 346 may quantify local deviations from the governing partial differential equations.

In various implementations, the training dataset 454 may include data samples generated from different reservoir configurations, time steps, and/or input conditions. For example, one or more reservoir simulators may be utilized to produce multiple fine-grid and coarse-grid simulations representing different geological models, well placement scenarios, or fluid injection rates, and accordingly, the high-resolution simulation results 340, coarse-grid simulation results 342, and coarse-grid residual 346 may represent multiple (often many) corresponding sets of training samples for various different reservoir simulations. The machine learning model manager 126 may train the subsurface simulation DDPM 432 using this diverse set of simulation results, facilitating generalization across a broad range of reservoir behaviors and spatial patterns.

The training dataset 454 may be provided to the machine learning model manager 126 to facilitate training a subsurface simulation DDPM 432. In particular, the machine learning model manager 126 may implement a diffusion model 458 to perform a forward diffusion process. For instance, the diffusion model 458 progressively adds noise to the high-resolution simulation results 340 according to a predefined noise schedule 460. The noise schedule 460 defines a sequence of discrete steps from t=0 to t=n, where t=0 represents the (clean) high-resolution simulation results 340, and t=n represents a maximally noised state approximating Gaussian noise.

Using the diffusion model 458, the machine learning model manager 126 may apply the noise schedule 460 to the high-resolution simulation results 340 to generate a series of noised high-resolution simulation results 462. Each noised high-resolution simulation result 462 may correspond to a different step t, and may include artificially added noise 464 sampled from a standard normal distribution. The noise schedule 460 may control the variance of the noise 464 added at each step, ensuring a smooth, progressive, and known corruption of the high-resolution simulation results 340.

The subsurface simulation DDPM 432 may be generated to reconstructed noise 466, or predict noise fields associated with the noise of an input sample. In connection with a sampler (described in more detail below), the predicted noise is used to generate high-resolution property fields. To elaborate, during training, the subsurface simulation DDPM 432 receives as input a randomly selected noised high-resolution simulation results 462(t) for a corresponding step t. Additionally the subsurface simulation DDPM 432 is guided by the conditioning data 456 to predict the noise that was added at that step. The conditioning data 456, including the coarse-grid simulation results 342 and the corresponding residual 346, provides the physics-based context and structural guidance that informs the noise predictions made by the subsurface simulation DDPM 432. These predictions are subsequently used by a sampler to iteratively reconstruct the high-resolution simulation result from an initial noise sample during inference.

In various implementations, such as the one shown in FIG. 4, the subsurface simulation DDPM 432 includes a neural network-based generative architecture 433 comprising one or more neural network layers arranged to model spatiotemporal structure in the simulation data. In some embodiments, the generative architecture 433 includes a U-Net or U-Net++ architecture, with encoder and decoder components linked by skip connections to preserve spatial detail. In other instances, the generative architecture 433 may be a convolutional denoising auto encoder, a probabilistic generative model such as a Monte Carlo Dropout network, or a large diffusion-based generative model trained to predict added noise. In yet other cases, the generative architecture 433 may include a multi-channel image-to-image neural network configured to accept structured conditioning data and perform resolution enhancement on simulation field data.

To elaborate, in some implementations, the generative architecture 433 is a convolutional neural network (CNN) that includes an encoder portion configured to transform structured simulation inputs into a latent feature representation. The encoder may include multiple convolutional layers, nonlinear activation functions (e.g., ReLU), and pooling operations that progressively reduce the spatial dimensions of the input while extracting multiscale features. For instance, the encoder may map a noised high-resolution simulation result 462(t), together with spatially aligned conditioning data 456, into a compressed vector or tensor representation that encodes features related to pressure gradients, fluid interfaces, geological boundaries, or other flow-relevant attributes. In this way, the encoder identifies latent patterns in the input data that relate to both spatial structure and physical significance.

Additionally, in various implementations, the generative architecture 433 includes a decoder portion formed by higher neural network layers. These layers may include upsampling operations, transpose convolutions, and skip connections to the encoder layers, enabling the decoder to reconstruct spatially resolved outputs from the latent feature representation. In some embodiments, the decoder may also include fully connected layers or output-specific modules configured to predict the noise 464 associated with a given step in the diffusion process. The decoder thus generates a reconstructed noise 466, which approximates the Gaussian noise originally applied to the high-resolution simulation result 340 at the step t. By decoding feature vectors into noise fields with spatial fidelity, the decoder enables accurate, physics-guided denoising during both training and inference.

To elaborate, the generative architecture 433 may be configured to perform a denoising task at various levels of corruption. As mentioned, the diffusion model 458 applies a noise schedule 460 to produce, for each high-resolution simulation result 340, a sequence of noised high-resolution simulation results 462. Each noised high-resolution simulation result 462 contains injected noise 464 of varying intensity based on the noise schedule 460. During training, the generative architecture 433 is provided with one such noised high-resolution simulation result 462(t), the corresponding step, and the conditioning data 456. The subsurface simulation DDPM 432 is accordingly trained to predict the noise 464 that was added at that specific step t.

Additionally, in various implementations, the generative architecture 433 is trained to reconstruct the noise field from the input sample by producing a reconstructed noise 466. This reconstructed noise 466 is compared to the noise 464 using a loss model 468, which computes a loss value. Feedback 469 is derived from the and used to train the generative architecture 433 via backpropagation. The loss model 468 may implement one or more loss functions (e.g., L2 loss, MSE loss, or a physics-informed loss component) to quantify the accuracy of the reconstructed noise 466 relative to the noise 464. Over successive iterations, the subsurface simulation DDPM 432 learns to accurately reverse the forward diffusion process for each of the scheduled noise steps t. This training process is repeated across many samples and steps, allowing the model to generalize across spatial structures and noise levels. For instance, the training process may be iterated over a predefined number of epochs, until convergence criteria are met, until loss minimization plateaus, or other criteria. In one or more instances, the training loop may be performed using stochastic gradient descent (SGD) or an Adam optimizer.

In various implementations, the machine learning model manager 126 may apply augmentation strategies to the training dataset 454 to improve model robustness. For example, the high-resolution simulation results 340 may be rotated, flipped, randomly masked, or modified by introducing additional noise patterns. These augmentations may increase the diversity of the training dataset and improve the generalization of the subsurface simulation DDPM 432 across different reservoir types, geometries, and/or flow regimes. In some cases, ensemble training, dropout sampling, and/or cross-validation may be employed to further improve model performance.

Additionally, the generative architecture 433 may be configured to jointly process the high-resolution simulation results 340 and the conditioning data 456. In one embodiment, the coarse-grid simulation results 342 and/or coarse-grid residual 346 may be concatenated with the noised high-resolution simulation result 462(t), such as being embedded within an intermediate latent space. The conditioning data 456 may provide structure-and physics-based context that anchors the generative process to physically plausible outcomes, and to the specific reservoir features indicated in the coarse-grid simulation results 342. In this way, the model may advantageously learn to reconstruct fine-scale reservoir features such as sharp saturation fronts or flow barriers that are not explicitly represented in the coarse-grid simulation results 342 alone.

As an illustrative example, the coarse-grid residual 346 may encode areas of high local imbalance or simulation error in the coarse-grid simulation 152. These areas may correspond with physical discontinuities, such as faults, breakthrough fronts, or other subsurface features that are under-resolved in the coarse-grid simulation. By conditioning on these residuals, the subsurface simulation DDPM 432 may learn to reproduce sharp features in the high-resolution outputs that honor both the physical PDE constraints and the structural information present in the coarse-grid simulation. As mentioned above, this capability of the subsurface modeling system 120 may be distinct from other methods, which apply smooth 2-dimensional flow fields on uniform grids, and accordingly lack the ability to represent or correct for such spatial discontinuities.

Accordingly, the subsurface simulation DDPM 432 is trained to predict noise fields within input noise samples and, together with a sampler, construct high-resolution reservoir property fields from the guidance of low-resolution coarse-grid inputs and residuals. While the subsurface simulation DDPM 432 is described with respect to training on pressure and saturation fields in reservoir simulations, it should be understood that similar DDPM architectures may be applied to a range of physical simulation outputs, including multiphase flow, CO₂ storage scenarios, or enhanced oil recovery models. Furthermore, the subsurface modeling system 120 may be utilized in connection with additional data types, such as permeability, porosity, or facies distributions, allowing for broader applicability to subsurface modeling problems. In this way, the training and implementation of the subsurface simulation DDPM 432 may enable resolution transformation and physics-based resolution upscaling across a wide variety of reservoir modeling workflows.

Once trained, in various implementations, the subsurface modelling system 120 uses the subsurface simulation DDPM 432 to automatically generate high-resolution target data from noise samples guided by coarse-grid target data.

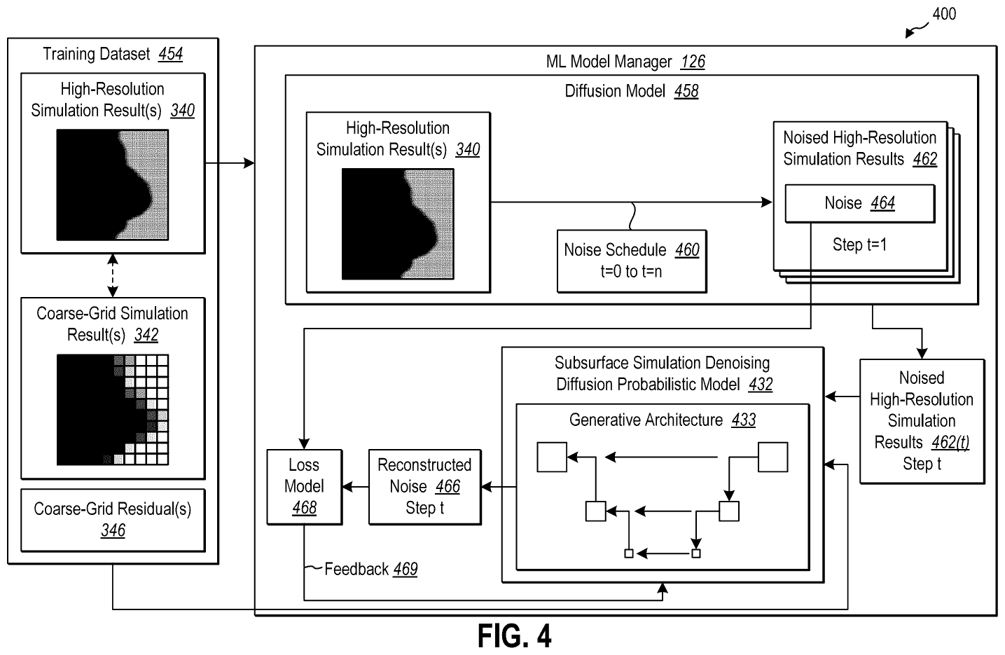

FIG. 5 illustrates a block diagram example of a workflow 500 for utilizing a trained subsurface simulation DDPM 432 for generating a high-resolution target reservoir property field 576, according to at least one embodiment of the present disclosure. In this figure, the subsurface simulation DDPM 432 represents a trained model with tuned neural network layers and other trained components.

As discussed, the subsurface simulation DDPM 432 may be generated to create high-resolution predictions based on low-resolution inputs and physics-based guidance data. Unlike during training, however, which operates on known high-resolution simulation results, during inference a randomly generated noise sample is provided as input, and the subsurface simulation DDPM 432 iteratively transforms this noise sample into a physically consistent, high-resolution simulation output using a reverse diffusion process.

For instance, as shown in FIG. 5, a target dataset 570 includes a noise sample 572 and target conditioning data 556. The noise sample 572 may be a multi-dimensional array of random values sampled from a standard Gaussian distribution. The noise sample 572 may match the dimensionality of the desired high-resolution reservoir property field 576 and serve as the initial input for the reverse diffusion process. The use of the noise sample 572 allows the generative architecture 433 to synthesize entirely new high-resolution outputs without requiring a known fine-grid simulation as input.

The target conditioning data 556 include target coarse-grid simulation results 542 and corresponding target coarse-grid residuals 546. Together, the target conditioning data 556 provides structural and physical context to guide the generative architecture 433 during each denoising step of the inference process.

The machine learning model manager 126 may implement the subsurface simulation DDPM 432 by providing the noise sample 572. At each step t, the generative architecture 433 receives the current or updated noised sampler, represented as the noised high-resolution simulation result 562(t) at step t. The subsurface simulation DDPM 432 also receives the current step t and the target conditioning data 556. The generative architecture 433 predicts the noise associated with step t as a predicted noise 566 at step t. This predicted noise 556 is passed to a sampler 574, which applies a reverse diffusion formula to generate an updated noised high-resolution simulation result 562(t-1) for the previous step t-1. The new/updated sample is then fed back into the subsurface simulation DDPM 432 to repeat the denoising process for the next step t-1.

The ML model manager 126 implements this inference loop iteratively for each step from t=n (original noise sample 572) to t=0. Each step incrementally reduces the noise present in the updated simulation result while incorporating guidance from the coarse-grid simulation result 542 and residual 546. For instance, the sampler 574 uses the predicted noise 566 to probabilistically reverse the noise schedule applied during training, ensuring that the iterative denoised outputs remain consistent with the statistical and physical patterns learned by the subsurface simulation DDPM 432. Upon completion of the final step t=0, the resulting sample corresponds to a fully denoised, high-resolution target reservoir property field 576.

The high-resolution target reservoir property field 576 may include predicted spatial distributions of physical quantities such as pressure, water saturation, gas saturation, or other relevant fluid properties across a fine-grid reservoir model. The high-resolution target reservoir property field 576 may be formatted as a multi-dimensional tensor or volumetric field, with each element corresponding to a grid cell in a simulated fine-resolution mesh. The high-resolution target reservoir property field 576 may facilitate advantageously obtaining fine-scale simulation results without executing a computationally expensive full-resolution numerical simulation. Indeed, by generating physically plausible outputs that reflect the underlying dynamics of the reservoir, the subsurface modelling system 120 can significantly accelerates workflows such as production forecasting, history matching, and scenario analysis, while maintaining geological and physical fidelity.

The high-resolution target reservoir property field 576 may be used in a variety of reservoir engineering tasks that traditionally require computationally intensive fine-grid simulations. For instance, the high-resolution reservoir property fields may support production forecasting by providing detailed flow field predictions under proposed well configurations. In some cases, the high-resolution reservoir property fields can facilitate rapid history matching by comparing simulated outputs to observed production data across many high-resolution realizations. Additionally, the high-resolution reservoir property fields may inform real-time or near-real-time decision-making for drilling and other downhole operations. For example, these property fields may be used to identify optimal drilling targets, adjust mud weights, and/or modify well trajectories based on predicted pressure or saturation gradients at fine spatial resolution. In carbon storage or enhanced oil recovery scenarios, the high-resolution property fields may be used to evaluate containment risks, optimize injection rates, and/or refine operational strategies under evolving subsurface conditions.

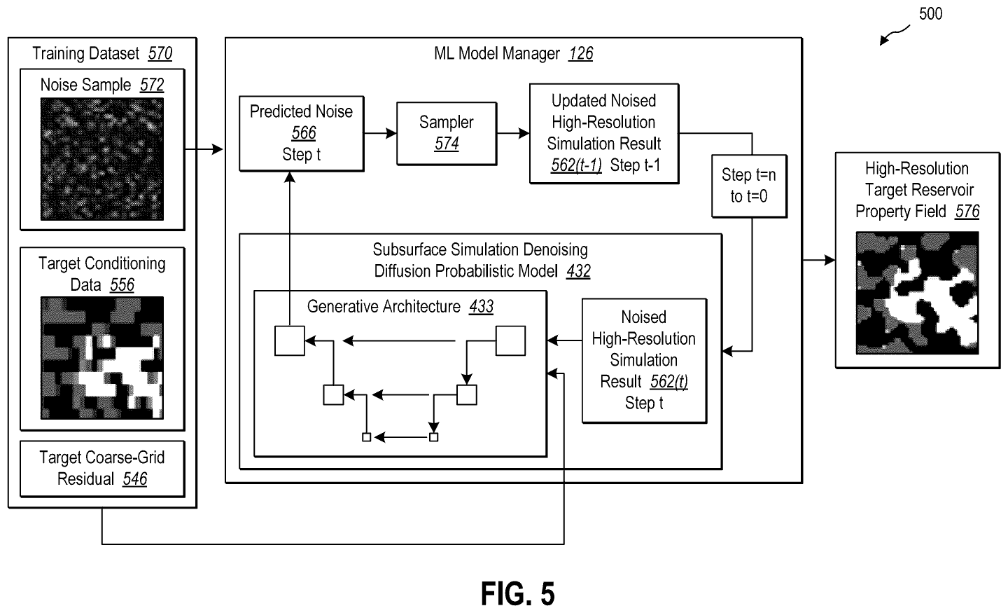

FIG. 6 illustrates an example three-dimensional reservoir model 600 generated using high-resolution outputs produced by the subsurface modelling system 120, according to at least one embodiment of the present disclosure. In various implementations, the reservoir model manager 128 may construct the reservoir model 600 based on one or more high-resolution outputs representing spatial distributions of physical properties such as pressure, saturation, or temperature across the reservoir volume. These high-resolution outputs may be generated as either two-dimensional slices or three-dimensional volumes, depending on the structure of the input data and the configuration of the machine learning model. For instance, in some cases, the subsurface modeling system 120 utilizes 2-dimensional data for generating 2-dimensional property fields via the generative ML techniques. In other cases, subsurface simulation DDPMs may be trained on three-dimensional coarse-grid inputs and residuals to produce volumetric predictions directly, resulting in fully 3-dimensional simulation property fields without requiring reconstruction from individual 2-dimensional slices.

The reservoir model 600 may represent a structured spatial grid covering the modeled reservoir domain, where each cell or voxel corresponds to a specific subsurface location and contains one or more predicted property values. These predicted values may be defined over a uniform or non-uniform grid, depending on the underlying reservoir simulation and input data geometry. In some embodiments, the reservoir model 600 may also include multiple property channels and/or time-dependent data, providing a dynamic representation of reservoir behavior with respect to a production time period. The reservoir model 600 may reflect realistic geological features, such as faults, flow barriers, or stratigraphic discontinuities, which are preserved through the use of physics-informed conditioning during inference.

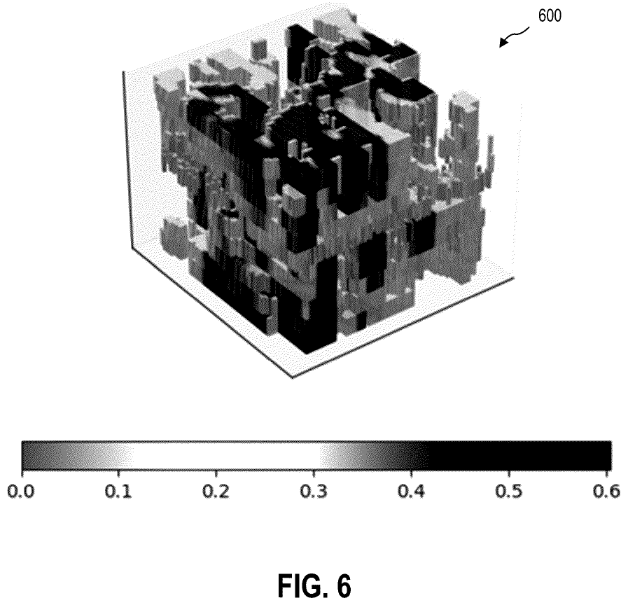

FIG. 7 illustrates an example time-evolving reservoir model 700 generated using sequential high-resolution simulation outputs produced by the subsurface modeling system 120, according to at least one embodiment of the present disclosure. In some implementations, the subsurface modeling system 120 may generate a series of high-resolution target reservoir property fields, each corresponding to a specific simulation timestep. These outputs may be either two-dimensional or three-dimensional depending on the structure of the training data and the implementation of a corresponding subsurface simulation DDPM. For instance, the subsurface modeling system 120 may generate the reservoir model 700 based on generating a first model 700(1) corresponding to a first time step, a second model 700(2) corresponding to a second timestep, and a third model 700(3) corresponding to a third timestep. In some cases, the timesteps may be in increments, of hours, days, weeks, months, or years. The subsurface modeling system 120 may generate any number of models in this way corresponding to any number of different timesteps of a given subsurface reservoir. In some cases, the reservoir model 700 may present the various discrete, timestep models for comparison and/or characterization of properties of the reservoir at the various timesteps. In some cases, the subsurface modeling system 120 may assemble these sequential models into a dynamic reservoir model which may include animations and/or dynamic updates that captures how key reservoir properties evolve over time. In yet another example, the various sequential models may be assembled into a single 4D tensor structure. For instance, the reservoir model 700 in this way may be capable of queried, visualized, and/or sliced along both spatial and temporal dimensions. In some embodiments, temporal interpolation or smoothing may be applied to create continuous representations of reservoir behavior between timesteps.

In this way, the reservoir model 700 may be an evolving and/or time-dependent reservoir model and may represent various reservoir properties, such as pressure, saturation, or other property fields at multiple temporal snapshots, forming a four-dimensional dataset. The time-evolving nature of the reservoir model 700 may be useful for a variety of time-sensitive operational decisions, such as adjusting injection or production strategies, optimizing well shut-ins, and forecasting reservoir performance under varying operational scenarios, among other decisions. In at least one example, the reservoir model 700 may facilitate examining how saturation fronts propagate over time to anticipate breakthrough events. In some cases, the reservoir model 700 can facilitate assessing the effectiveness of waterflooding and gas injection programs. By capturing both the spatial and temporal complexity of reservoir dynamics, the reservoir model 700 may facilitate more accurate, proactive, and data-driven reservoir management.

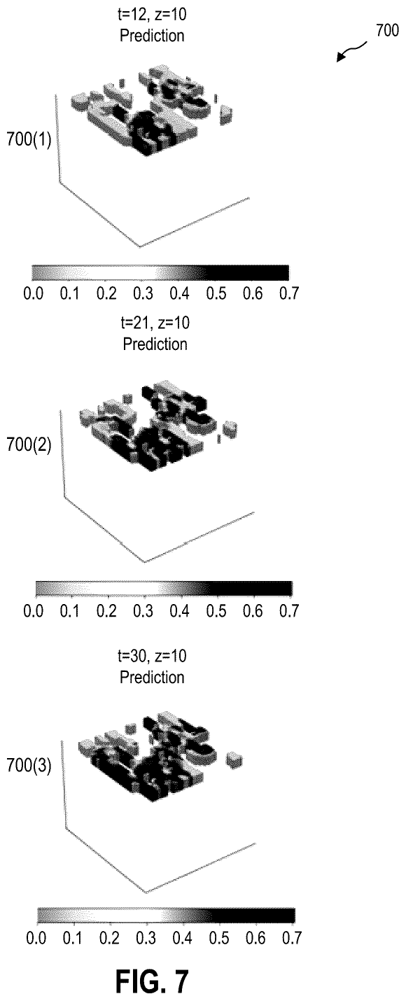

FIG. 8 illustrates a flow diagram for a method 800 or a series of acts for modeling a subsurface reservoir, according to at least one embodiment of the present disclosure. While FIG. 8 illustrates acts according to one embodiment, alternative embodiments may add to, omit, reorder, or modify any of the acts of FIG. 8. In some embodiments, the acts of FIG. 8 are performed as a method. In some embodiments, the acts of FIG. 8 are performed by a computer system. In some embodiments, the acts of FIG. 8 are performed as instructions stored on a computer-readable storage medium.

In some embodiments, the method 800 includes an act 810 of receiving coarse-grid simulation results for the subsurface reservoir. For example, the act 810 may include receiving coarse-grid simulation results for the subsurface reservoir, wherein the coarse-grid simulation results are based on a coarse-grid simulation of the subsurface reservoir and have a low resolution that is less than a high resolution.

In some embodiments, the method 800 includes an act 820 of generating a reservoir model using a subsurface simulation ML model. For example, in some cases, the act 820 includes generating a reservoir model using a subsurface simulation machine learning model that is trained to denoise input noise samples using coarse-grid simulation samples as conditioning data to predict high-resolution target reservoir property fields at the high resolution, wherein the high-resolution target reservoir property fields indicate a predicted structure and one or more predicted flow properties for target subsurface reservoirs.

In some embodiments, the method 800 includes an act 830 of providing the reservoir model for operating a wellbore based on the reservoir model.

In some embodiments, the method 800 further includes receiving a residual of the coarse-grid simulation of the subsurface reservoir and generating the reservoir model using the subsurface simulation ML model by applying the residual as a static conditioning variable, wherein the subsurface simulation ML model is further generated to use static coarse-grid residuals as conditioning data in addition to the coarse-grid simulation samples to predict the high-resolution target reservoir property fields for the target subsurface reservoirs. In some embodiments, the residual is computed once before inferencing with the subsurface simulation ML model for use as the static conditioning variable. In some embodiments, the residual is not recomputed during inferencing with the subsurface simulation ML model.

In some embodiments, the coarse-grid simulation of the subsurface reservoir is based on a system of 3 or more partial differential equations. In some embodiments, the coarse-grid simulation is based on Darcy's law and the conservation of mass. In some embodiments, the coarse-grid simulation models one or more discontinuities of the subsurface reservoir, and the reservoir model generated by the subsurface simulation ML model includes predictions of the one or more discontinuities of the subsurface reservoir. In some embodiments, the one or more discontinuities are indicated as one or more empty cells in the coarse-grid simulation, and the reservoir model includes one or more empty cells for representing the one or more discontinuities. In some embodiments, the one or more discontinuities represent one or more locations of substantially no saturation in the subsurface reservoir. In some embodiments, the coarse-grid simulation of the subsurface reservoir is based on a non-uniform grid, and coarse-grid simulation results provide conditioning to the subsurface simulation ML model to process grid non-uniformities.

In some embodiments, the method 800 further includes generating the coarse-grid simulation results for the subsurface reservoir based on executing the coarse-grid simulation of the subsurface reservoir, and providing the coarse-grid simulation results to the subsurface simulation ML model to generate the reservoir model. In some embodiments, the high-resolution target reservoir property fields are generated for a plurality of time steps, and the reservoir model comprises a time-dependent representation of the subsurface reservoir that characterizes changes in the predicted structure and flow properties over time. In some embodiments, the reservoir model is a 3-dimensional reservoir model and is generated based on generating a plurality of high-resolution target reservoir property fields assembling the plurality of high-resolution target reservoir property fields into layers of the 3-dimensional reservoir model. In some embodiments, the coarse-grid simulation has a resolution of at most 40 cells per dimension. In some embodiments, the high resolution is at least 160 cells per dimension. These example resolutions for the coarse-grid simulation and the high-resolution should be understood as illustrative, and the resolution of the coarse-grid simulation and the high-resolution may be any other resolution, for example, as dictated by a size of an underlying reservoir simulation.

In some embodiments, the subsurface simulation ML model is a denoising diffusion probabilistic model (DDPM) trained to generate the high-resolution target reservoir property fields from noise samples. In some embodiments, the subsurface simulation ML model has a U-Net architecture. In some embodiments, the method 800 further includes providing the reservoir model to operate the wellbore includes providing the reservoir model for identifying a quantity of water to inject into the wellbore to achieve a fluid flow from the subsurface reservoir.

In some embodiments, the method 800 further includes generating high-resolution simulation results based on executing a fine-grid simulation of the subsurface reservoir; converting the high-resolution simulation results to noised high-resolution simulation results through an iterative forward diffusion process of adding noise to the high-resolution simulation results; and generating the subsurface simulation ML model to predict the noise added through the forward diffusion process to recover the high-resolution simulation results from the noised high-resolution simulation results. In some embodiments, generating the subsurface simulation ML model further includes conditioning the subsurface simulation ML model with the coarse-grid simulation results and with a residual computed from the coarse-grid simulation.

In some embodiments, the subsurface simulation ML model is a generative machine learning model.

In some embodiments, the subsurface simulation ML model is a denoising diffusion probabilistic model (DDPM) trained to generate high-resolution simulation images from Gaussian noise.

In some embodiments, the subsurface simulation ML model is trained to map random input noise from a standard distribution to a probability distribution of a class of images including the target simulation images.

In some embodiments, the method 800 further includes generating intermediate simulation results based on interpolating the simulation results and upsampling at the high resolution.

In some embodiments, the intermediate simulation results include at least some noise based on the interpolating.

In some embodiments, generating the reservoir model includes providing the intermediate simulation results to the subsurface simulation ML model as guidance for directing a diffusion process of the subsurface simulation ML model.

In some embodiments, the subsurface simulation ML model incorporates the intermediate simulation results as intermediate diffused states between random noise inputs and generated target simulation images.

In some embodiments, the coarse-grid simulation is a reservoir fluid simulation.

In some embodiments, the coarse-grid simulation simulates a fluid flow of the subsurface reservoir.

In some embodiments, the coarse-grid simulation is based on the following formula:

$$∇ \cdot [ α K \frac{{k}_{r , m} ( {S}_{m} )}{{μ}_{m} {B}_{m}} ( ∇ {p}_{m} - {γ}_{m} ∇ z ) ] - β \frac{\partial }{\partial t} ( ∅ \frac{{S}_{m}}{{B}_{m}} ) + {\sum }_{ω} \frac{{q}_{sc , m}^{ω}}{{V}_{b}} = 0$$

$$Where :$$

$$k denotes the permeability ,$$

$${k}_{r} relative permeability ,$$

$$μ is viscosity ,$$

$$B is the formation volume factor ,$$

$$p is pressure ,$$

$$S is saturation ,$$

$$∅ is porosity ,$$

$$t is time ,$$

$$γ is specific weight ,$$

$$Q is the source / sink terms ,$$

$$Z is depth ,$$

$${V}_{b} is the bulk volume , and$$

$$α and β are unit field constants .$$

In some embodiments, the coarse-grid simulation is a 2-dimensional simulation.

In some embodiments, the coarse-grid simulation is a 3-dimensional simulation.

In some embodiments, the simulation includes one or more discontinuities for representing a structure of the subsurface reservoir.

In some embodiments, the one or more discontinuities include one or more empty cells, pixels, voxels, or data points having no value or magnitude.

In some embodiments, the one or more discontinuities are based on an underlying value or magnitude being below a threshold.

In some embodiments, the one or more discontinuities represent one or more of a varying permeability field or a varying porosity field of the subsurface reservoir.

In some embodiments, the geological model represents the predicted structure based on including one or more predicted discontinuities in the target simulation images for the subsurface reservoir.

In some embodiments, the predicted structure includes one or more of a predicted, shape, size, orientation, or location of the subsurface reservoir.

In some embodiments, the one or more discontinuities include one or more empty cells, pixels, voxels, or data points having no value or magnitude.

In some embodiments, the one or more discontinuities represent one or more locations of substantially no saturation in the subsurface reservoir.

In some embodiments, the one or more discontinuities are based on an underlying value or magnitude being below a threshold.

In some embodiments, the geological model is 2-dimensional.

In some embodiments, the geological model is 3-dimensional.

In some embodiments, the method 800 further includes generating a physics- informed conditioning variable and conditioning the subsurface simulation ML model based on the physics-informed conditioning variable to generate the reservoir model.

In some embodiments, the physics-informed conditioning variable is based on a residual from the coarse-grid simulation.

In some embodiments, the residual is calculated based on incorporating discontinuities in the simulation results.

In some embodiments, generating the subsurface model includes predicting a set of values for the target simulation images using the subsurface simulation ML model, and representing at least one value of the set of values as a discontinuity in the reservoir model based on the at least one value being below a threshold.

In some embodiments, the method further includes generating a plot, graph, or other visual representation of the reservoir model.

In some embodiments, the method further includes presenting the reservoir model via a graphical user interface of a client device.

In some embodiments, the method further includes providing the reservoir model for simulating fluid flow of a formation or reservoir.

In some embodiments, the method further includes providing the reservoir model for creating or adjusting a drilling plan for a wellbore.

In some embodiments, the method further includes providing the reservoir model for creating or adjusting a drilling plan for a wellbore.

In some embodiments, the method further includes the reservoir model for adjusting one or more drilling parameters of a downhole tool for forming a wellbore.

In some embodiments, the method further includes providing the reservoir model for identifying a location for a wellbore.

In some embodiments, the method further includes providing the reservoir model for identifying a quantify of water to inject into the wellbore to achieve a fluid flow from the subsurface reservoir.

In some embodiments, the method 800 includes generating high-resolution simulation results from a fine-grid simulation of the subsurface reservoir; converting the high-resolution simulation results to noise samples through an iterative forward process; and training the subsurface simulation ML model to map noise from a standard distribution to a probability distribution of the high-resolution simulation results based on a backwards process of iterative denoising the noise samples to recover the high-resolution simulation results.

In some embodiments, the high-resolution simulation results include one or more discontinuities representing a structure of the subsurface reservoir, and wherein the one or more discontinuities are in the form of one or more empty cells, empty pixels, empty voxels, or other missing data points in the high-resolution simulation results.

In some embodiments, training the subsurface simulation ML model includes iteratively denoising the noise samples to recover the high-resolution simulation results, including the one or more discontinuities.

In some embodiments, converting the high-resolution simulation results includes iteratively applying Gaussian noise from a varied schedule of distributions.

In some embodiments, the method 800 further includes iteratively applying Gaussian noise until the noise samples are isotropic to the normal Gaussian distribution.

Turning now to FIG. 9, this figure illustrates certain components that may be included within a computer system 900. One or more computer systems 900 may be used to implement the various devices, components, and systems described herein.

The computer system 900 includes a processor 901. The processor 901 may be a general-purpose single-or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor 901 may be referred to as a central processing unit (CPU). Although just a single processor 901 is shown in the computer system 900 of FIG. 9, in an alternative configuration, a combination of processors (e.g., an ARM and DSP) could be used.

The computer system 900 also includes memory 903 in electronic communication with the processor 901. The memory 903 may include computer-readable storage media and can be any available media that can be accessed by a general purpose or special purpose computer system. Computer-readable media that store computer-executable instructions are non-transitory computer-readable media (device). Computer-readable media that carry computer-executable instructions are transmission media. Thus, by way of example and not limitations, embodiment of the present disclosure can comprise at least two distinctly different kinds of computer-readable media: non-transitory computer-readable media (devices) and transmission media.

Both non-transitory computer-readable media (devices) and transmission media may be used temporarily to store or carry software instructions in the form of computer readable program code that allows performance of embodiments of the present disclosure. Non-transitory computer-readable media may further be used to persistently or permanently store such software instructions. Examples of non-transitory computer-readable storage media include physical memory (e.g., RAM, ROM, EPROM, EEPROM, etc.), optical disk storage (e.g., CD, DVD, HDDVD, Blu-ray, etc.), storage devices (e.g., magnetic disk storage, tape storage, diskette, etc.), flash or other solid-state storage or memory, or any other non-transmission medium which can be used to store program code in the form of computer-executable instructions or data structures and which can be accessed by a general purpose or special purpose computer, whether such program code is stored or in software, hardware, firmware, or combinations thereof.

Instructions 905 and data 907 may be stored in the memory 903. The instructions 905 may be executable by the processor 901 to implement some or all of the functionality disclosed herein. Executing the instructions 905 may involve the use of the data 907 that is stored in the memory 903. Any of the various examples of modules and components described herein may be implemented, partially or wholly, as instructions 905 stored in memory 903 and executed by the processor 901. Any of the various examples of data described herein may be among the data 907 that is stored in memory 903 and used during execution of the instructions 905 by the processor 901.

A computer system 900 may also include one or more communication interfaces 909 for communicating with other electronic devices. The communication interface(s) 909 may be based on wired communication technology, wireless communication technology, or both. Some examples of communication interfaces 909 include a Universal Serial Bus (USB), an Ethernet adapter, a wireless adapter that operates in accordance with an Institute of Electrical and Electronics Engineers (IEEE) 802.11 wireless communication protocol, a Bluetooth® wireless communication adapter, and an infrared (IR) communication port.

The communication interfaces 909 may connect the computer system 900 to a network. A “network” or “communications network” may generally be defined as one or more data links that enable the transport of electronic data between computer systems and/or modules, engines, or other electronic devices, or combinations thereof. When information is transferred or provided over a communication network or another communications connection (either hardwired, wireless, or a combination of hardwired or wireless) to a computing device, the computing device properly views the connection as a transmission medium. Transmission media can include a communication network and/or data links, carrier waves, wireless signals, and the like, which can be used to carry desired program or template code means or instructions in the form of computer-executable instruction or data structures and which can be accessed by a general purpose or special purpose computer.

A computer system 900 may also include one or more input devices 911 and one or more output devices 913. Some examples of input devices 911 include a keyboard, mouse, microphone, remote control device, button, joystick, trackball, touchpad, and lightpen. Some examples of output devices 913 include a speaker and a printer. One specific type of output device that is typically included in a computer system 900 is a display device 915. Display devices 915 used with embodiments disclosed herein may utilize any suitable image projection technology, such as liquid crystal display (LCD), light-emitting diode (LED), gas plasma, electroluminescence, or the like. A display controller 917 may also be provided, for converting data 907 stored in the memory 903 into one or more of text, graphics, or moving images (as appropriate) shown on the display device 915.

The various components of the computer system 900 may be coupled together by one or more buses, which may include one or more of a power bus, a control signal bus, a status signal bus, a data bus, other similar components, or combinations thereof. For the sake of clarity, the various buses are illustrated in FIG. 9 as a bus system 919.

The techniques described herein may be implemented in hardware, software, firmware, or any combination thereof, unless specifically described as being implemented in a specific manner. Any features described as modules, components, or the like may also be implemented together in an integrated logic device or separately as discrete but interoperable logic devices. If implemented in software, the techniques may be realized at least in part by a non-transitory processor-readable storage medium comprising instructions that, when executed by at least one processor, perform one or more of the methods described herein. The instructions may be organized into routines, programs, objects, components, data structures, etc., which may perform particular tasks and/or implement particular data types, and which may be combined or distributed as desired in various embodiments.

Further, upon reaching various computer system components, program code in the form of computer-executable instructions or data structures can be transferred automatically or manually from transmission media to non-transitory computer-readable storage media (or vice versa). For example, computer executable instructions or data structures received over a network or data link can be buffered in memory (e.g., RAM) within a network interface module (NIC), and then eventually transferred to computer system RAM and/or to less volatile non-transitory computer-readable storage media at a computer system. Thus, it should be understood that non-transitory computer-readable storage media can be included in computer system components that also (or even primarily) utilize transmission media.

The embodiments of the subsurface modeling system have been primarily described with reference to wellbore drilling operations; the subsurface modeling system described herein may be used in applications other than the drilling of a wellbore. In other embodiments, the subsurface modeling system according to the present disclosure may be used outside a wellbore or other downhole environment used for the exploration or production of natural resources. For instance, the subsurface modeling system of the present disclosure may be used in a borehole used for placement of utility lines. Accordingly, the terms “wellbore,” “borehole” and the like should not be interpreted to limit tools, systems, assemblies, or methods of the present disclosure to any particular industry, field, or environment.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements. Additionally, as used herein, the term “and/or” includes any and all combinations of one or more of the associated listed items.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method for modeling a subsurface reservoir, comprising:
receiving coarse-grid simulation results for the subsurface reservoir, wherein the coarse-grid simulation results are based on a coarse-grid simulation of the subsurface reservoir and have a low resolution that is less than a high resolution;
generating a reservoir model using a subsurface simulation machine learning (ML) model that is trained to denoise input noise samples using coarse-grid simulation samples as conditioning data to predict high-resolution target reservoir property fields at the high resolution, wherein the high-resolution target reservoir property fields indicate a predicted structure and one or more predicted flow properties for target subsurface reservoirs; and
providing the reservoir model for operating a wellbore based on the reservoir model.

2. The method of claim 1, further comprising receiving a residual of the coarse-grid simulation of the subsurface reservoir and generating the reservoir model using the subsurface simulation ML model by applying the residual as a static conditioning variable, wherein the subsurface simulation ML model is further generated to use static coarse-grid residuals as conditioning data in addition to the coarse-grid simulation samples to predict the high-resolution target reservoir property fields for the target subsurface reservoirs.

3. The method of claim 2, wherein the residual is computed once before inferencing with the subsurface simulation ML model for use as the static conditioning variable.

4. The method of claim 3, wherein the residual is not recomputed during inferencing with the subsurface simulation ML model.

5. The method of claim 1, wherein the coarse-grid simulation of the subsurface reservoir is based on a system of 3 or more partial differential equations.

6. The method of claim 5, wherein the coarse-grid simulation is based on Darcy's law and the conservation of mass.

7. The method of claim 5, wherein the coarse-grid simulation models one or more discontinuities of the subsurface reservoir, and the reservoir model generated by the subsurface simulation ML model includes predictions of the one or more discontinuities of the subsurface reservoir.

8. The method of claim 7, wherein the one or more discontinuities are indicated as one or more empty cells in the coarse-grid simulation, and the reservoir model includes one or more empty cells for representing the one or more discontinuities.

9. The method of claim 8, wherein the one or more discontinuities represent one or more locations of substantially no saturation in the subsurface reservoir.

10. The method of claim 1, wherein the coarse-grid simulation of the subsurface reservoir is based on a non-uniform grid, and coarse-grid simulation results provide conditioning to the subsurface simulation ML model to process grid non-uniformities.

11. The method of claim 1, further comprising generating the coarse-grid simulation results for the subsurface reservoir based on executing the coarse-grid simulation of the subsurface reservoir, and providing the coarse-grid simulation results to the subsurface simulation ML model to generate the reservoir model.

12. The method of claim 1, wherein the subsurface simulation ML model is a denoising diffusion probabilistic model (DDPM) trained to generate the high-resolution target reservoir property fields from noise samples.

13. The method of claim 1, wherein the subsurface simulation ML model has a U-Net architecture.

14. The method of claim 1, wherein the high-resolution target reservoir property fields are generated for a plurality of time steps, and the reservoir model comprises a time-dependent representation of the subsurface reservoir that characterizes changes in the predicted structure and flow properties over time.

15. The method of claim 1, wherein the reservoir model is a 3-dimensional reservoir model and is generated based on generating a plurality of high-resolution target reservoir property fields and assembling the plurality of high-resolution target reservoir property fields into layers of the 3-dimensional reservoir model.

16. The method of claim 1, further comprising:
generating high-resolution simulation results based on executing a fine-grid simulation of the subsurface reservoir;
converting the high-resolution simulation results to noised high-resolution simulation results through an iterative forward diffusion process of adding noise to the high-resolution simulation results; and
generating the subsurface simulation ML model to predict the noise added through the forward diffusion process to recover the high-resolution simulation results from the noised high-resolution simulation results.

17. The method of claim 16, wherein generating the subsurface simulation ML model further includes conditioning the subsurface simulation ML model with the coarse-grid simulation results and with a residual computed from the coarse-grid simulation.

18. The method of claim 1, wherein providing the reservoir model to operate the wellbore includes providing the reservoir model for identifying a quantity of water to inject into the wellbore to achieve a fluid flow from the subsurface reservoir.

19. A system, comprising:
a processor;
memory in electronic communication with the processor; and
instructions stored in the memory and executable by the processor to cause the system to perform operations of:
receiving coarse-grid simulation results for a subsurface reservoir, wherein the coarse-grid simulation results are based on a coarse-grid simulation of the subsurface reservoir and have a low resolution that is less than a high resolution;
generating a reservoir model using a subsurface simulation machine learning (ML) model that is trained to denoise input noise samples using coarse-grid simulation samples as conditioning data to predict high-resolution target reservoir property fields at the high resolution, wherein the high-resolution target reservoir property fields indicate a predicted structure and one or more predicted flow properties for target subsurface reservoirs; and
providing the reservoir model for operating a wellbore based on the reservoir model.

20. A computer-readable storage medium having instructions stored thereon which, when executed by a processor, cause the processor to operations of:
receiving coarse-grid simulation results for a subsurface reservoir, wherein the coarse-grid simulation results are based on a coarse-grid simulation of the subsurface reservoir and have a low resolution that is less than a high resolution;
generating a reservoir model using a subsurface simulation machine learning (ML) model that is trained to denoise input noise samples using coarse-grid simulation samples as conditioning data to predict high-resolution target reservoir property fields at the high resolution, wherein the high-resolution target reservoir property fields indicate a predicted structure and one or more predicted flow properties for target subsurface reservoirs; and
providing the reservoir model for operating a wellbore based on the reservoir model.
